(19) United States
(12) Patent Application Publication
(10) Pub. No.: US 2006/0102923 A1
(43) Pub. Date: May 18, 2006

(54) Optical element housing package

(76) Inventors: Takuya Oda, Nagano-shi (JP); Shinsuke Ohashi, Maibara-shi (JP)

Correspondence Address: MORGAN & FINNEGAN, L.L.P., 3 WORLD FINANCIAL CENTER, NEW YORK, NY, 10281-2101, US

(21) Appl. No.: 11/280,073

(22) Filed: Nov. 15, 2005

(30) Foreign Application Priority Data
Nov. 16, 2004 (JP) 2004-331855

(51) Int. Cl. H01L 33/00; H01L 31/0232

(52) U.S. Cl. 257/100; 257/432

(57) ABSTRACT

In a package for housing an optical element, if the size of an optical element chip and of a metal cap increase, the flatness of a flange of the metal cap can be maintained when the metal cap is bonded by seam welding to the package body, and the optical element can be mounted with sufficient airtightness. An optical element housing package has a substrate (10) provided, on the upper surface thereof, with a element mounting portion on which an optical element (12) is to be mounted, a metal frame (30) secured to the upper surface of the substrate around the element mounting portion, and a metal cap(40) which airtightly holds a glass window (24) at the center thereof, has a peripheral flange (44) bonded to the metal frame by thermo-compression, and airtightly houses the optical element inside thereof. The flange (44) of the metal cap (40) is provided with a stress absorbing portion (46) at an inner side of a portion bonded to the metal frame.

### BACKGROUND OF THE INVENTION

1. Field of the Invention

The present invention relates to a structure of a package for housing an optical element and, especially, relates to an optical element housing package wherein a metal cap for holding a glass window is provided with a flange, and the flange is bonded, by seam welding, to a body of the package having an optical element mounted thereon.

2. Description of Related Art

A package for housing an optical element is provided with a glass window through which light incident upon and/or emitted from the optical element housed therein is transmitted. When the glass window is bonded to a metal cap and a metal cap is bonded to a package body, airtightness is required therebetween. For example, a conventional mass production DMD (Digital Micromirror Device) package is provided with a metal cap which is adapted to airtightly seal the glass window, which permits light to pass therethrough, to a ceramic package. As the metal cap must be highly airtight, in order to increase a sealing area between the glass and the metal, a thick glass and a thick metal cap have been used. Further, in order to provide high airtightness, the ceramic package and the metal cap are connected by thermo-compression bonding (seam welding), and consequently, the metal cap is provided with a flange which defines a thin portion, as shown in FIG. 1.

It is expected that, along with an increase in the number of pixels of an optical element, the chip will become larger and, consequently, a metal cap for a larger glass window is required. To this end, in order to ensure airtight sealing, the flange must be as flat as possible. However, distortion tends to occur at the connection between the glass and the metal during seam welding, resulting in a possible occurrence of cracks, etc. Under these circumstances, it is expected that use of a large flange undesirably invites a deterioration of the reliability of the product.

In the related prior art, Japanese Unexamined Patent Publication (Kokai) No. 11-97964 discloses a metal container for an electronic element in which, in order to prevents metal chips from being produced and scattered during resistance welding, a base and a cover, which are both provided on their outer peripheries with flanges, are provided. The base has lead wires extending therethrough. The flange of the base or the cover is provided with an annular projection. The flanges are welded together by resistance welding, and thereby, an electronic element, which is electrically connected to the lead wires, is sealed in the metal container. An annular groove is provided on the flange of the cover or the base so that the annular projection provided on the flange of the base or the cover can be engaged in the annular groove. With this structure, positioning of the cover and the base can be ensured, and metal chips are not produced or scattered during resistance welding.

Also, Japanese Unexamined Patent Publication (Kokai) No. 10-242318 (JPP'318) discloses a package for housing an electronic element in which, when a metal cap is welded to a flange member attached to an insulating base, the flange can be separated from the insulating base, or cracks can occur in the insulation base. Consequently, the airtightness of the container of the package for housing an electronic element cannot be maintained. To overcome this problem, in JPP'318, the outer side of the outer periphery of the flange is made thicker than the remaining portion so that the thermal stress in welding can be appropriately reduced and the mechanical strength can be surely obtained.

As mentioned above, in a conventional optical element housing package, if the size of a chip of an optical element to be mounted increases and a metal cap whose size is increased accordingly must be used, it is difficult for the flange of the metal cap to maintain flatness and, thus, at the time of bonding the metal cap to the package body by seam welding, sufficient airtightness to the mounted optical element may not be maintained.

### SUMMARY OF THE INVENTION

It is an object of the present invention to provide an optical element housing package in which, if the size of the optical element chip or the metal cap increases, an optical element can be mounted with sufficient airtightness by maintaining the flatness of a flange of a metal cap when the metal cap is bonded to a package body by seam welding.

In order to achieve the above-mentioned object, according to the present invention, there is provided an optical element housing package comprising a substrate provided, on its upper surface, with an element mounting portion on which an optical element is to be mounted, a metal frame secured to the upper surface of the substrate around the element mounting portion, and a metal cap which airtightly holds a glass window at a center of the cap has a peripheral flange bonded to the metal frame by thermo-compression bonding and airtightly houses the optical element in the cap, wherein the flange of the metal cap is provided with a stress absorbing portion located on an inner side than a connection between the cap and the metal frame.

With this arrangement, because the flange of the metal cap is provided, at an inner side than the connection to the metal frame, with the stress absorbing portion, even if the flange of the metal cap is deformed by heat when the metal cap is welded to the package body by seam welding, the stress is absorbed by the stress absorbing portion provided on the flange, and the flange is maintained flat when it is welded to the package body, and thus, the metal cap is kept airtight.

In an embodiment, the metal cap is made of a body which is provided, at its central portion, with a frame-shaped thick portion having an opening in which the glass window is held, the flange is formed integrally with the body at the outer periphery thereof to define a thin portion, and the stress absorbing portion has a curved cross-section.

With this structure, as the body of the metal cap which holds the glass window defines a thick portion, the contact surface area between the thick glass window material and the inner periphery of the opening of the metal cap can be increased, and accordingly, the glass window can be airtightly held. On the other hand, the flange integrally formed with the outer periphery of the body defines a thin portion, and the flange has a curved cross section to define the stress absorbing portion. Consequently, the stress, generated when the peripheral portion of the flange located outside of the stress absorbing portion is welded to the metal frame of the package body by seam welding, is absorbed by the curved portion to thereby enhance close contact between the flange of the metal cap and the metal frame of the package body, thus leading to highly effective sealing of the inside of the metal cap.

Preferably, the metal cap and the metal frame are made of kovar. The thick body which has, at the center, an opening for holding the glass window and the peripheral thin flange are integrally formed by cutting. The stress absorbing portion having a curved cross section is formed by pressing, etc.

### BRIEF DESCRIPTION OF THE DRAWINGS

FIG. 1 is a cross-sectional view showing a structure of a conventional optical element housing package;

FIG. 2 is an enlarged cross-sectional view of the portion “A” in FIG. 1 and FIG. 3; and

FIG. 3 is a cross-sectional view showing a structure of an optical element housing package according to the present invention.

### DETAILED DESCRIPTION OF THE PREFERRED EMBODIMENTS

An embodiment of the present invention will be explained, in detail, below with reference to the drawings and will be compared to the prior art.

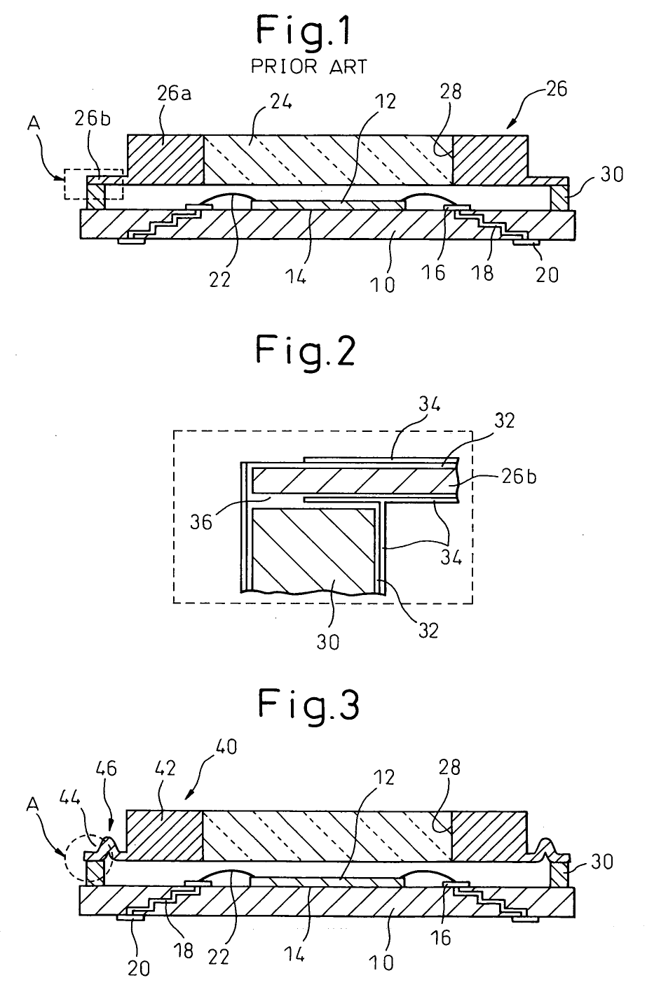

FIG. 1 is a cross-sectional view showing a structure of a DMD (Digital Micromirror Device) package as an example of a known optical element housing package.

On an upper surface of an insulation substrate made of ceramic, etc., a element mounting area 14 for mounting an optical element 12, for example, a micromirror, is provided. A large number of bonding pads 16 are provided at the periphery of the element mounting area 14 on the upper surface of the insulation substrate 10. Each pad 16 is connected to an external connection pad 20 on the lower surface of the insulation substrate 10, through inside wiring 18 of the insulation substrate 10.

After the optical element 12 is mounted on the element mounting area 14 of the insulation substrate 10, electrode terminals of the optical element 12 and the bonding pads 16 on the insulation substrate 10 are mutually connected with wires 22 by a known wire-bonding process.

In a metal cap 26 having a center opening 28 for holding a glass window 24, in order to provide a sufficient contact surface area between the peripheral side surface of the glass window 24 and the inner periphery of the opening 28 to thereby maintain airtightness therebetween, the glass window 24 itself and a body 26a having the opening 28 are made thick.

On the other hand, an outwardly extending flange 26b provided at the periphery of the body 26a of the metal cap 26 is made thin, in order that the stress generated upon seam welding can be absorbed as much as possible, whereby the flange 26b can be bonded airtightly by seam welding (thermo-compression bonding), to a metal frame 30 secured to the insulation substrate 10 around the optical element 12. The metal frame 30 is secured to the upper surface of the insulation substrate 10 at a region outside of the bonding pad 16 and is formed in a frame-shape corresponding to the flange 26b of the metal cap 26.

The metal cap 26 having the thick body 26a and the thin flange 26b is integrally formed by cutting an appropriate metal, for example, kovar. Likewise, the metal frame 30 secured to the upper surface of the insulation substrate 10 is formed by cutting an appropriate metal, for example, kovar.

As can be seen from FIG. 2 showing a portion “A” in FIG. 1, nickel plating 32 and gold plating 34 are applied to the kovar surfaces of the flange 26b of the metal cap 26 and the metal frame 30, which are mutually bonded by seam welding. However, in the outer peripheral side region 36, at which the flange 26b and the metal frame 30 are connected to each other, the gold plating 34 is diffused by heat upon seam welding, the gold-plated layer disappears and only the nickel-plated layer 32 remains.

As mentioned above, in the conventional optical element housing package as shown in FIG. 1, the larger the size of the optical element 12 to be mounted, the larger the metal cap 26 becomes. However, it becomes more difficult to maintain the flatness of the flange 26b of the metal cap 26 as the metal cap becomes larger.

FIG. 3 shows a cross-sectional view of a structure of a DMD (Digital Micromirror Device) package as an example of an optical element housing package according to the present invention.

In FIG. 3, according to the present invention, the glass window 24 itself and the body 42 of the metal cap 40 having the opening 28 are made thick to obtain a sufficient mutual contact area between the peripheral side surface of the glass window 24 and the inner periphery of the opening 28 in order to ensure airtightness therebetween, and the flange 44 outwardly projecting from the periphery of the body 42 of the metal cap 40 is made thin, in order that the stress generated upon seam welding can be absorbed as much as possible, to meet the requirement that the flange 44 must be bonded airtightly by seam welding (thermo-compression) to the metal frame 30 secured to the insulation substrate 10 around the optical element 12, as in the prior art shown in FIG. 1. In the present invention, the stress absorbing portion 46 located at a portion between the flange 44 of the metal cap 40 and the metal frame 30, in order to achieve airtight sealing for the mounted optical element 12 by guaranteeing the airtightness between the metal cap 40 and the metal frame 30 on the insulation substrate 10 upon bonding by seam welding.

The stress absorbing portion 46 is formed, for example, by pressing, etc., at the periphery of the flange 44 to have a curved cross-section. Namely, after the metal cap 40 having the thick body 42 and the thin flange 44 is integrally formed by cutting an appropriate metal, for example, kovar, the metal cap 40 is bent at the inner side region of flange 44 over the entire periphery by a pressing machine (not shown). Consequently, the inner portion of the flange 44 having a predetermined small thickness is curved in an upper direction, and the curved portion defines the stress absorbing portion 46.

The outer portion of the flange 44 of the metal cap 40 remains flat so as to define a bonding region for bonding to the metal frame 30 by seam welding. The flange 44 of the metal cap 40 and the metal frame 30, which are mutually bonded by seam welding, are made of an appropriate metal, for example, kovar, and nickel plating 32 and gold plating 34 are applied to the surfaces thereof, as in the prior art. On the outer peripheral side region 36 (FIG. 2), at which the flange 44 and the metal frame 30 are connected, the gold plating 34 is diffused by heat upon seam welding, the gold-plated layer disappears and only the nickel-plated layer 32 remains, as in the prior art. Accordingly, FIG. 2 corresponds to the region A in FIG. 3.

According to the present invention, as shown in FIG. 3, because the stress absorbing portion 46 having a curved cross-section is provided at the flange 44 of the metal cap 40, distortion stress generated when the metal cap 40 is connected to the metal frame 30 of the package substrate 10 having the optical element 12 mounted thereon by seam weld bonding, in a known method using a thermo-compression roller (not shown), is absorbed by the stress absorbing portion 46, to thereby enhance the close contact, under thermo-compression, between the flange 44 of the metal cap 40 and the metal frame 30 at the bonding region and achieve a sufficient airtight seal. At this time, distortion stress generated at the interface between the glass window 24 and the metal is also released, thus resulting in a highly reliable product.

The optical element 12 mounted on the package is, for example, a DMD (Digital Micromirror Device). In the DMD, light emitted from an external light source (not shown) passes through the glass window 24 of the package and is impinged upon a micromirror, i. e., the optical element 12 provided therein. The light reflected from the micromirror is projected on a screen, etc. (not shown), through a projector lens (not shown). By electrically driving the micromirrors, such as turning ON/OFF, etc. the micromirrors, light reflected by the micromirrors can be controlled.

The optical element housing package according to the present invention can be advantageously used for a DMD, because the latter requires high airtightness for the micromirror housed therein.

As described above, according to the present invention, because the stress absorbing portion is provided on the flange of the metal cap, the flatness and the close contact between the flange of the metal cap and the metal frame of the package can be improved when the metal cap is connected to the package body by seam welding, and the optical element mounted on the package can be sealed with sufficient airtightness. Accordingly, if the size of the optical element increases and the size of the metal cap itself also increases in the future, along with an increase in the number of pixels, the present invention can be advantageously applied to a element which require high airtightness, such as a DMD (Digital Micromirror Device), and the reliability of a product can be enhanced.

Although an embodiment of the present invention has been explained above with reference to the drawings, the present invention is not limited to the above embodiment, and can be changed and modified into various forms within the spirit and scope of the present invention.

1. An optical element housing package comprising:
a substrate provided, on its upper surface, with an element mounting portion on which an optical element is to be mounted;
a metal frame secured to the upper surface of the substrate around the element mounting portion; and
a metal cap which airtightly holds a glass window at a center of the cap, having a peripheral flange bonded to the metal frame by thermo-compression bonding, and airtightly housing the optical element in the metal cap,
wherein the flange of the metal cap being provided with a stress absorbing portion located between the cap and the metal frame.

2. An optical element housing package according to claim 1, wherein the metal cap is made of a body which is provided, at its central portion, with a frame-shaped thick portion having an opening in which the glass window is held, the flange is formed integrally with the body at the outer periphery thereof to define a thin portion, and the stress absorbing portion has a curved cross-section.

3. An optical element housing package according to claim 1, wherein the metal cap and the metal frame are made of kovar, and have surfaces plated with nickel and gold.
